(19) United States
(12) Patent Application Publication
(10) Pub. No.: US 2013/0015461 A1
(43) Pub. Date: Jan. 17, 2013

(54) Light-emitting Device Capable of Producing White Light And Light Mixing Method For Producing White Light With Same

(71) Applicant: Kuen-Chiuan Lin, (US)

(72) Inventor: Kuen-Chiuan Lin, (US)

(73) Assignee: KUN HSIN TECHNOLOGY INC., Taipei City (TW)

(21) Appl. No.: 13/181,527

(22) Filed: Jul. 13, 2011

(51) Int. Cl. H01L 33/08; H01L 33/52; H01L 33/30

(52) U.S. Cl. 257/76; 257/89; 257/E33.059

(57) ABSTRACT

A light-emitting device capable of producing white light includes at least two types of LED elements and at least one encapsulant material. Each of the LED elements has an epitaxial light-emitting layer grown on a substrate; and the epitaxial light-emitting layers for the LED elements are the same series of AlGaInN materials having emission wavelengths in a region from violet to green light and different from one another by at least 30 nm. The encapsulant material encapsulates the LED elements and contains an adequate amount of fluorescent powder, which can be excited to emit complementary color lights to mix with color lights from the LED elements to produce bluish, yellowish, greenish or reddish white light. At least two types of the white light-emitting devices can be differently arrayed in a module or a system to produce a white light with high color-rendering index and good light mixing effect.

### BACKGROUND OF THE INVENTION

1. Field of the Invention

The present invention relates to a light-emitting device capable of producing white light and a light mixing method thereof. The white light-emitting device includes at least two types of LED elements, each of which including an epitaxial light-emitting layer, i.e. an LED chip, and at least one encapsulant material. The epitaxial light-emitting layers for the at least two types of LED elements are the same series of epitaxial materials having emission wavelengths different from one another. The at least one encapsulant material contains an adequate amount of fluorescent powder that can be excited by the color light emitted from the corresponding LED element to produce a complementary color light having a specific wavelength. The excited color lights and the color lights of the LED elements mix with one another to produce a variety of hued white light. At least two different types of the white light-emitting devices can be differently arrayed in a module or a system to produce a white light with high color-rendering index and good light mixing effect.

2. Description of the Prior Arts

Compound semiconductors for a light-emitting diode (LED) utilize the principle of direct conversion of electric energy into light energy. When a voltage is applied across a positive and a negative electrode in the semiconductor, electric current flows through the semiconductor. When an electron meets a hole, it falls into a lower energy level and releases energy in the form of a photon. The wavelength of the light emitted depends on the energy level of the material of semiconductor. The emitted light can be a visible light of various colors having a wavelength ranged between 380 nm and 780 nm, or an invisible light having a wavelength falling out of the above-mentioned range. Due to its advantages of long service life, quick response time, small volume, light weight, operable at low voltage from 2 to 5 volts, low pollution, low power consumption, low heat production (i.e. high energy efficiency), mass-producible and wide applications, the white-light LED has become a main direction of development in the recent photoelectric industrial fields. Currently, the white-light LEDs for illumination application are mainly used as reading lights in car and decorative lights, while more than 95% of the remaining white-light LEDs are used as a backlight source for liquid crystal displays (LCDs), particularly a small-size backlight source. Among others, the currently most promising markets for white-light LEDs include the backlight source for cell phone color screens and the flashlight for cell phones equipped with a digital camera; and the future markets for white-light LEDs include the backlight source for large-size LCDs and the light source for global illumination.

A mixed light that is perceived by human eyes as white light is obtained by mixing two or more color lights having different wavelengths, such red, blue and green lights or blue and yellow lights. The LEDs that are manufactured by currently available techniques for mixing different color lights to produce white light can be divided into two types, namely, single-chip and multi-chip LEDs.

The multi-chip LED uses three LEDs, namely, red, green and blue (RGB) LEDs, and mixes the color lights emitted from the three LEDs to produce a white light. The multi-chip LED can be advantageously adjusted according to actual need to obtain desired light color. The LED for mixing lights to produce white light mixes red, green and blue (RGB) lights to produce a white-light for use in illumination. The white light so produced has best color saturation and good color-rendering index. However, since the red LED (AlGaInP) and the blue and green LEDs (AlInGaN) are quite different in terms of their materials and structures, it is necessary to use correct ratio of color lights of different wavelengths as well as adequate luminous intensity matching ratio to obtain the white light with good color-rendering index. Therefore, there are difficulties in implementing light mixing using the conventional RGB multi-chip LED. Further, the red LED and the blue and green LEDs are also different in operating voltage (V_{f}), light attenuation, temperature property and service life. Therefore, three sets of feedback circuits are needed to control the three color LEDs to produce the white light. That is, the light mixing mechanism and the control circuit for the multi-chip LED are comparatively complicated, bringing the color of the mixed white light to change with time, which would seriously adversely affect the cost and stability of the illumination system using same.

The currently commercialized single-chip white LED can be manufactured with three different techniques:

(1) Using blue LED with yellow fluorescent powder: The fluorescent powder used is mainly yttrium aluminum garnet (Y₃Al₁₅G₁₂, YAG) fluorescent powder emitting yellow light. When the yellow light emitted from the YAG fluorescent powder mixes with the unabsorbed blue light emitted from the blue LED, a white light can be obtained. Since the white light produced by the white LED formed of single-color blue LED and yellow fluorescent powder has comparatively lower color saturation and low color-rendering index (Ra), an object being illuminated by this type of white light looks less bright, and particularly, the red color is comparatively unclear, rendering the white color not suitable for human eyes, particularly when being used over a long period of time.

(2) Using blue LED with red and green fluorescent powder: The fluorescent powder is mainly sulfur-containing fluorescent powder. When the red and green lights emitted from the sulfur-containing fluorescent powder mix with the unabsorbed blue light emitted from the blue LED, a white light can be obtained. While the white light produced in this way has comparatively good color saturation and high color-rendering index, it is uneasy to prepare the fluorescent powder with correct ratio to produce white light with proper color temperature. Further, since the uniformity of the fluorescent powder could not be easily controlled, the white LED could not be easily mass-produced.

(3) Using ultraviolet (UV) LED with red, green and blue (RGB) fluorescent powder: The UV light emitted from the UV LED simultaneously excites three or more types of fluorescent powder that respectively emit red, blue and green light, and the three color lights mix with one another to produce a white light. While the use of an UV LED to excite the RGB fluorescent powder for producing white light can be advantageously achieved with relatively easy control circuit, the UV LED has comparatively lower luminous efficiency. Further, the epoxy encapsulating the LED chip tends to be yellowed and deteriorated after having been irradiated by the UV light emitted from the UV LED over a long time, which would inevitably bring the whole illumination system to have lowered luminous efficiency and fail to meet the requirement of energy saving and carbon reduction.

There are many inventions disclosing white LEDs. However, as a matter of fact, these prior art white LEDs do not produce white light with excellent color-rendering index and light mixing effect because they fail to effectively overcome or break through the long-existing LED structural problems.

For example, U.S. Pat. No. 6,765,237 discloses a white light emitting device, which includes one single LED formed by coating a yellow fluorescent layer on one single epitaxial chip, and encapsulating the chip and the fluorescent layer with epoxy. Due to the electro-optical conversion effect, the epitaxial chip emits single-wavelength blue light that irradiates on the fluorescent layer, so that the electronic energy of the chemical structure of the fluorescent layer changes from ground state into excited state to emit yellow fluorescence, which mixes with the blue light to produce a near-white light source.

U.S. Pat. No. 5,998,925 discloses a hybrid LED formed by encapsulating a GaN chip and YAG with a resin. The GaN chip emits a blue light (λₚ=400-530 nm, W_{d}=30 nm), and the YAG fluorescent powder containing Ce₃+ obtained by sintering at high temperature is excited by the blue light to emit a yellow light having a peak wavelength of 550 nm. The blue LED chip is mounted in a reflective cup and covered by a thin layer of the resin containing the YAG. The YAG fluorescent powder absorbs part of the blue light emitted from the blue LED chip and mixes with the remaining blue light to produce a near-white light.

Taiwan Patent Publication No. 385063 discloses a new white LED, which is formed by combining an ultraviolet (UV) LED wafer and RGB fluorescent powder. The new white LED is featured by that the UV LED wafer emits a UV light, which excites the RGB fluorescent powder coated or plated on the surface of the UV LED wafer, so as to produce a white light. The fluorescent powder can be blended into transparent glue and then packaged along with the UV wafer into small-size chips, which are then encapsulated using transparent glue to form a large-size LED chip.

Taiwan Patent Publication No. 200520262 (Nichia Corporation) discloses a light-emitting device, which includes a light-emitting element capable of emitting light having an emission spectrum in a range from near-UV region to visible light region and having a main emission peak wavelength, as well as phosphors. The light-emitting device includes two or more types of phosphors that either have luminescent centers of direct transition type or are directly excited by the light-emitting element. However, this type of light-emitting device has the following main drawbacks: the UV LED has low luminous efficiency, and the epoxy having been irradiated by UV light over a long time tends to become yellowed and therefore blocks the light emission of the LED.

Taiwan Patent No. 156177 (Nichia Corporation) discloses an area light-emitting device, which includes a semiconductor light-emitting element, such as blue LED, and a type of photoluminescent fluorescent material. Lights emitted from the semiconductor light-emitting element and the photoluminescent fluorescent material are mixed to produce a white light. Wherein, the semiconductor light-emitting element is indium nitride and the fluorescent material includes more than two garnet oxides, so that more than two types of fluorescent light can be produced. However, since the preparation and distribution of the two types of fluorescent powder in correct ratio could not be easily controlled to achieve good light mixing effect, it is difficult to mass-produce this type of area light-emitting device.

In view of the above disadvantages in the prior art white LEDs, the inventor has developed a light-emitting device capable of producing white light. The white light-emitting device includes at least two types of LED elements and at least one encapsulant material. The LED elements respectively have an epitaxial light-emitting layer (i.e. an LED chip), and the epitaxial light-emitting layers of the LED elements are the same series of materials with emission wavelengths in the region from violet to green light and different from one another by at least 30 nm. The encapsulant material encapsulates the LED elements and contains an adequate amount of fluorescent powder, which can excited to emit other complementary color lights to mix with the color lights emitted from the LED elements to produce at least a bluish to yellowish white light and a greenish to reddish white light. At least two types of the white light-emitting devices can be differently arrayed in a system or in a module to emit a variety of complementary color lights, which mix with one another to produce a white light having increased color-rendering index and upgraded light mixing effect. In this manner, the white light-emitting device of the present invention can be manufactured with simplified manufacturing process at reduced cost to obtain high good yield, and can be easily controlled with simple control circuit to produce white light with good color-rendering index and light mixing effect.

### SUMMARY OF THE INVENTION

A primary object of the present invention is to solve the problems in the prior art white LEDs by providing a light-emitting device capable of producing white light and a light mixing method for producing white light.

Another object of the present invention is to provide a light-emitting device capable of producing white light that includes epitaxial light-emitting layers (i.e. LED chips) with close material properties, and can therefore be manufactured with simplified manufacturing process at reduced cost to obtain high good yield, and the voltage and current for controlling the white light-emitting device is simple.

To achieve the above and other objects, the light-emitting device capable of producing white light according to the present invention includes at least two types of LED elements respectively having an epitaxial light-emitting layer grown on a substrate, and at least one encapsulant material for encapsulating the LED elements. The epitaxial light-emitting layers for the LED elements are the same series of materials to emit color lights in a region from violet to green light but having wavelengths different from each other by at least 30 nm. The encapsulant material contains an adequate amount of fluorescent powder that can be excited by the color lights emitted from the LED elements to emit complementary color lights having specific wavelengths, so that the excited color lights and the color lights of the LED elements mix with one another to produce bluish, yellowish, greenish or reddish white light. And, the light mixing method for producing white light according to the present invention includes the step of preparing at least two types of the white light-emitting devices of the present invention and arraying them in a module or a system, so that multiple color lights emitted from the white light-emitting devices mix with one another to produce a white light with high color-rendering index and good color saturation.

Since the epitaxial light-emitting layers have close material properties, the white light-emitting devices can be manufactured with simplified manufacturing process and the same voltage and current can be used to control the epitaxial light-emitting layers to enable reduced manufacturing cost and high good yield.

In an embodiment of the present invention, the materials for the epitaxial light-emitting layers are In_{z}Ga_{1-z}N, wherein 0≦z≦1.

Further, in another embodiment of the present invention, the materials for the epitaxial light-emitting layers are AlₓGa_{y}In_{1-x-y}N, wherein 0≦x, y≦1.

Preferably, the encapsulant material for the present invention is silicone.

Or preferably, the encapsulant material for the present invention is epoxy.

Further, in the present invention, two or more layers of fluorescent powder can be contained in the encapsulant material.

Preferably, the light-emitting device of the present invention is structured as an LED lamp.

Or preferably, the light-emitting device of the present invention is structured as a PLCC (plastic leadless chip carrier).

Or preferably, the light-emitting device of the present invention is structured as an SMD (Surface Mount Device).

According to an embodiment of the present invention, the encapsulant material is omitted from the light-emitting device. Instead, the fluorescent powder is directly coated on the LED chips, and a transparent layer, such as SiO₂ or Si₃N₄, is formed over the fluorescent powder coating to serve as a protective layer. In this design, only the electrodes of the LED elements are exposed from the transparent layer for electrically connecting to a lead frame or a base of the LED elements via bonding wires.

Preferably, the LED elements for the present invention use a chip bonding glue selected from the group consisting of silver paste, thermally conductive and electrically insulating adhesive, metal-powder-containing adhesive, diamond-powder-containing resin, graphite-powder-containing resin, and eutectic metals.

To achieve the above and other objects, the light-emitting device capable of producing white light according to the present invention includes:

at least two types of LED elements respectively having an epitaxial light-emitting layer, i.e. an LED chip, grown on a substrate; the epitaxial light-emitting layers for the LED elements being the same series of materials to emit color lights in a region from violet to green light but having wavelengths different from each other by more than 30 nm; that is, the LED elements have different emission wavelengths; and

at least one encapsulant material for encapsulating the LED elements; the encapsulant material containing an adequate amount of fluorescent powder, which can be excited by the color lights emitted from the LED elements to emit complementary color lights, and the excited color lights mixing with the color lights from the LED elements to produce a white light.

With the above arrangements, the fluorescent powder contained in the encapsulant material absorbs the color lights from the LED elements and emits other complementary color lights having specific wavelength ranges, which mix with the color lights from the LED elements. Since there are at least two types of LED elements, the white light-emitting device of the present invention can produce a bluish to yellowish white light and another greenish to reddish white light.

More particularly, each of the LED elements for the white light-emitting device of the present invention includes:

at least one lead frame serving as electrical connection pins;

a chip bonding glue being optionally provided on the lead frame;

a substrate being provided on the chip bonding glue for an epitaxy having a specific wavelength range to grow thereon;

an epitaxial light-emitting layer being grown on the substrate, and the epitaxial light-emitting layer further including an n-GaN, a multiple quantum well (MQW) layer and a p-GaN;

two transparent electrodes being provided on the p-GaN and the n-GaN of the epitaxial light-emitting layer;

a p-type electrode being provided on the p-GaN of the epitaxial light-emitting layer or on the transparent electrode that is located on the p-GaN;

an n-type electrode being provided on the n-GaN or on the transparent electrode that is located on the n-GaN;

two contacts being provided on the p-type and the n-type electrode; and

two bonding wires for electrically connecting the contacts on the n-type and p-type electrodes to the lead frame.

In the light mixing method for producing white light according to a preferred embodiment of the present invention, at least two types of the white light-emitting devices of the present invention are provided and coordinately arrayed in a module or a system in different manners.

In the light mixing method for producing white light according to another preferred embodiment of the present invention, the at least two types of the white light-emitting devices respectively include LED elements with epitaxial light-emitting layers having different emission wavelengths, and are alternately arranged one by one in the module or the system; or alternately arranged row by row in the module or the system; or irregularly alternately arranged in the module or the system.

In the light mixing method for producing white light according to the present invention, the at least two types of the white light-emitting devices according to the present invention arrayed in the module or the system respectively includes at least two types of LED elements and at least one encapsulant material for encapsulating the LED elements. The LED elements respectively have an epitaxial light-emitting layer, and the epitaxial light-emitting layers for the LED elements are the same series of materials but have different emission wavelengths. The encapsulant material contains an adequate amount of fluorescent powder that can be excited by the LED elements to emit at least four different complementary color lights, such as blue, blue-green, green, yellow, orange, red lights, and the excited color lights mix with the color lights emitted from the LED elements to produce the white light with high color-rendering index and good light mixing effect.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 shows a first embodiment of the light-emitting device capable of producing white light according to the present invention being structured as an LED lamp;

FIG. 2 shows a second embodiment of the light-emitting device capable of producing white light according to the present invention being structured as a PLCC or an SMD;

FIG. 3 shows a third embodiment of the light-emitting device capable of producing white light according to the present invention with the LED chips thereof being coated with fluorescent powder and protectively covered by a transparent layer;

FIG. 4 shows two types of the white light-emitting devices of the present invention having epitaxial light-emitting layers with different emission wavelengths are alternately arranged one by one;

FIG. 5 shows two types of the white light-emitting devices of the present invention having epitaxial light-emitting layers with different emission wavelengths are alternately arranged row by row;

FIG. 6 shows two types of the white light-emitting devices of the present invention having epitaxial light-emitting layers with different emission wavelengths are alternately arranged one by one in one row; and

FIG. 7 shows two types of the white light-emitting devices of the present invention having epitaxial light-emitting layers with different emission wavelengths are irregularly alternately arranged in one row with two first-type light-emitting devices disposed between two second-type light-emitting devices.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals. It is understood the accompanying drawings are illustrated only for assisting in describing the present invention and are not necessarily in compliance with the exact or precise size proportion and part arrangement of a real product manufactured through implementing the present invention. Therefore, the size proportion and part arrangement shown in the accompanying drawings are not intended to limit the present invention, which is intended to be limited only by the appended claims.

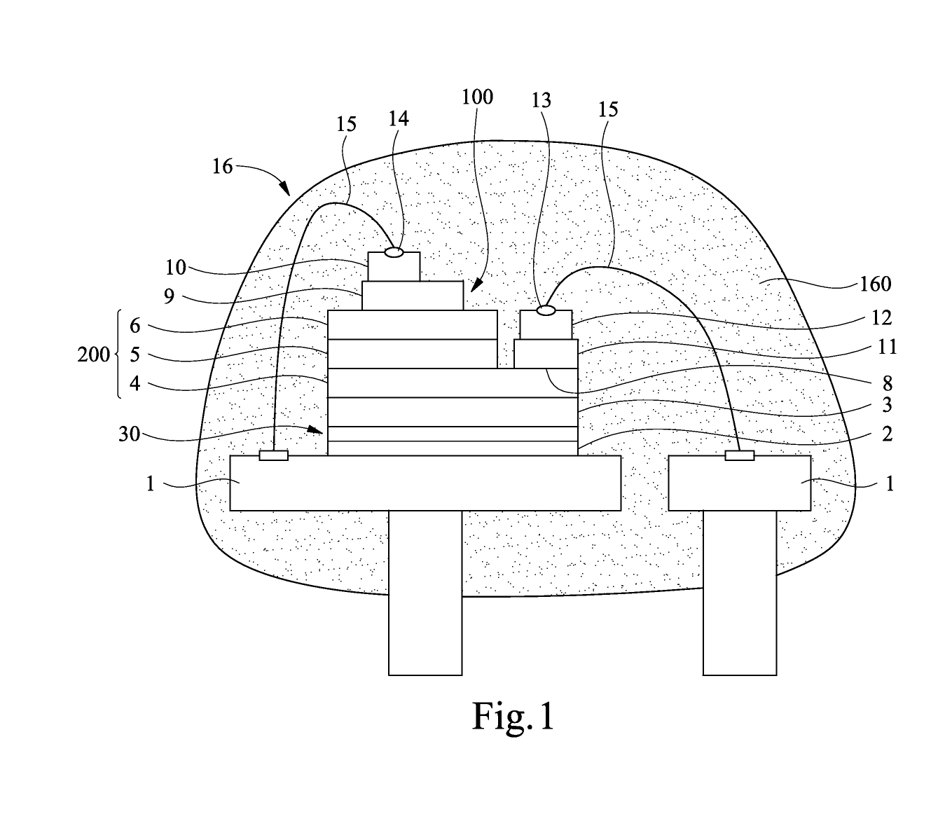

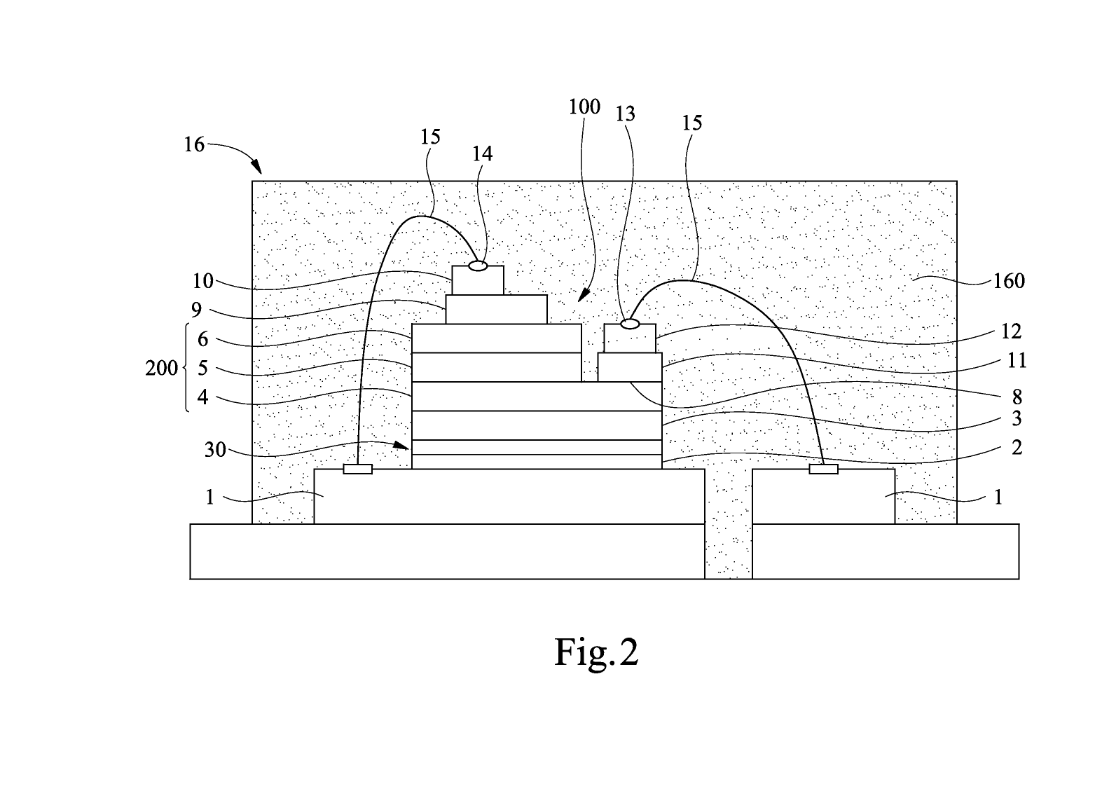

Please refer to FIGS. 1 and 2 that are structural views of a first and a second embodiment, respectively, of the light-emitting device capable of producing white light according to the present invention, which will also be briefly referred to as “white light-emitting device” herein. In the first embodiment, the white light-emitting device is structured as an LED (light-emitting-diode) lamp, and in the second embodiment, the white light-emitting device is structured as a PLCC (plastic leadless chip carrier) or an SMD (surface mounted device). In both the first and the second embodiment, the white light-emitting device of the present invention includes at least two types of LED elements 100 and at least one encapsulant material 16.

Each of the LED elements 100 includes a substrate 3, on which an epitaxial light-emitting layer 200 (i.e. an LED chip) is deposited or grown. The epitaxial light-emitting layers 200 of the at least two LED elements 100 have emission spectrums in a region from violet to green light with their wavelengths different from one another by more than 30 nm. In the illustrated embodiments of the present invention, the substrates 3 are sapphire without being limited thereto. That is, the substrates 3 may also be SiC, Si, or any other material, which all fall in the protective scope of the present invention, for growing epitaxial light-emitting layers 200 with specific emission wavelength ranges. For the substrates 3 made of sapphire to have improved photoelectric property, the sapphire substrates used in the present invention can be non-patterned sapphire substrates (NSS) or patterned sapphire substrates (PSS), which all fall in the protective scope of the present invention. Further, for the substrates 3 to have increased reflectivity, a distributed Bragg reflector (DBR) 30 is provided behind each of the substrates 3. And, in the present invention, to enable simplified manufacturing process, control with same voltage and current, low manufacturing cost, easy control and high good yield, the epitaxial light-emitting layers 200 in the same series of materials are grown on the substrates 3. In the illustrated embodiments of the present invention, the epitaxial light-emitting layers 200 are of the same series of materials capable of emitting lights that are in a region from violet to green light and have two different wavelengths. In the embodiments of the present invention, the epitaxial light-emitting layers 200 can be AlGaInN or InGaN without being limited thereto. That is, any epitaxial light-emitting layers 200 that are the same series of materials capable of emitting lights in a region from violet to green light but having wavelengths different from one another by more than 30 nm all fall in the protective scope of the present invention. Further, in the present invention, the materials for the epitaxial light-emitting layers 200 may be AlₓGa_{y}In_{1-x-y}N or In_{z}Ga_{1-z}N, wherein 0≦x, y, z≦1.

The encapsulant material 16 encapsulates the LED elements 100 to complete the white light-emitting device of the present invention. The encapsulant material 16 contains an adequate amount of fluorescent powder 160. The fluorescent powder 160 can be excited by the color lights emitted from the LED elements 100 to emit complementary color lights having appropriate wavelengths, which mix with the color lights from the LED elements 100 to produce white light. In the illustrated embodiments of the present invention, the encapsulant material 16 is epoxy without being limited thereto. For example, the encapsulant material 16 can also be silicone or any other suitable material, which also fall in the protective scope of the present invention. Further, for the LED elements 100 to produce white lights, two types of fluorescent powder 160 are contained in the encapsulant material 16, namely, yellow and red fluorescent powder without being limited thereto. That is, all types of fluorescent powder 160 of different colors that can emit excited light to mix with the color lights from the LED elements 100 to produce white light are within the protective scope of the present invention. In the illustrated embodiments, the yellow fluorescent powder 160 is Y₃Al₁₅G₁₂ (YAG) or cerium-doped YAG (Y₃Al₁₅G₁₂:Ce), and the red fluorescent powder 160 is a sulfide or europium-doped strontium sulfide (SrS:Eu). Further, in the illustrated embodiments of the present invention, the encapsulant material 16 is a single-layer structure without being limited thereto. The encapsulant material 16 can also be formed as a two-layer or a multi-layer structure by providing one or more additional layers of the encapsulant material 16 over a first layer of the fluorescent powder-containing encapsulant material 16, in order to obtain desired light shape and finely adjust the amount of the fluorescent powder 160.

With the above arrangements, the two types of fluorescent powder 160 contained in the encapsulant material 16 absorb the color lights from the LED elements 100 to thereby emit other color lights having specific wavelength ranges, and the color lights emitted from the fluorescent powder 160 mix with the color lights from the LED elements 100 to produce white light. The white light-emitting device according to the present invention also includes electrodes 10, 12 that are provided at predetermined positions to provide energy for the LED elements 100 to emit color lights. The electrodes 10, 12 are connected via bonding wires 15 to a lead frame 1 having downward extended pins, so as to provide the white light-emitting device as an LED lamp, as shown in FIG. 1. Alternatively, the electrodes 10, 12 are connected via bonding wires 15 to a lead frame 1 having a flat bottom surface, so as to provide the light-emitting device as a PLCC or an SMD, as shown in FIG. 2.

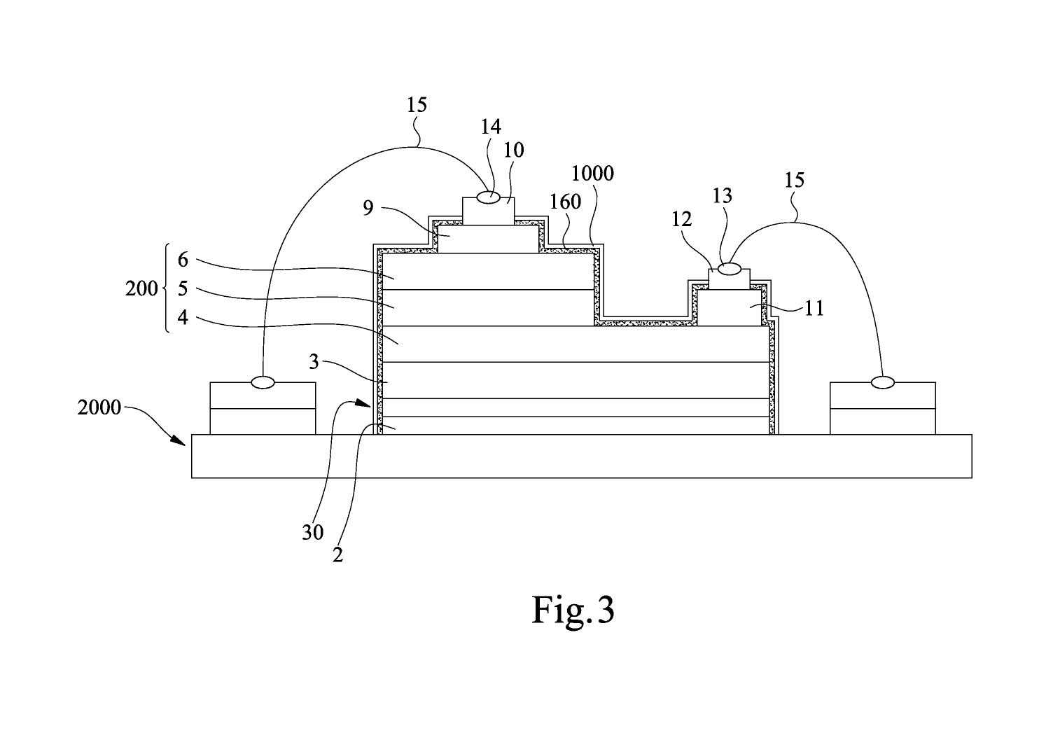

FIG. 3 is a structural view of a third embodiment of the light-emitting device capable of producing white light according to the present invention. In the third embodiment, the LED elements 100 do not include the encapsulant material 16 containing fluorescent powder 160, but include a protective transparent layer 1000 and is coated with a layer of fluorescent powder 160. Please refer to FIGS. 1 and 2 along with FIG. 3. As shown, each of the LED elements 100 in the first, second and third embodiments includes at least one lead frame 1, a chip bonding glue 2, a distributed Bragg reflector (DBR) 30, a substrate 3, an epitaxial light-emitting layer 200, transparent electrodes 9 and 11, a p-type electrode 10, an n-type electrode 12, contacts 14 and 13, and bonding wires 15.

The at least one lead frame 1 serves as electrical connection pins. In FIG. 1, the lead frame 1 has downward extended pins. The LED element 100 shown in FIG. 2 is different from that shown in FIG. 1 in that the lead frame 1 in FIG. 2 has a flat bottom surface. And, the LED element 100 shown in FIG. 3 is different from those shown in FIGS. 1 and 2 in that the encapsulant material 16 is omitted and the LED elements 100 are coated with a layer of fluorescent powder 160 and then covered by a protective transparent layer 1000. It is understood the lead frame 1 for the present invention is not limited to the above illustrated embodiments, and electrical connection pins in any form are all included in the protective scope of the present invention. Further, while there are two lead frames 1 shown in the illustrated embodiments, it is understood the number of the lead frames 1 is not limited to two but can be one or more than two, depending on the material of the substrate 3 and the design of the white light-emitting device. For example, a substrate 3 made of SiC has only one lead frame 1 and one of the electrodes is located below the substrate 3.

The chip bonding glue 2 is optionally provided on the lead frame 1, and can be selected from the group consisting of silver paste, thermally conductive and electrically insulating adhesive, metal-powder-containing adhesive, diamond-powder-containing resin, graphite-powder-containing resin, and eutectic metals. However, it is understood the chip bonding glue 2 for the present invention is not limited to the above-mentioned materials but may also be any other bonding materials.

The substrate 3 is located on the chip bonding glue 2, and the DBR 30 is located behind the substrate 3.

The epitaxial light-emitting layer 200 is located on the substrate 3 and includes an n-GaN 4, a multiple quantum well (MQW) laser layer 5 and a p-GaN 6. The epitaxial light-emitting layer 200 can be a single-wire vertical LED structure or a two-wire LED structure without being limited thereto. That is, the epitaxial light-emitting layer 200 can also be arranged in other manners, which all fall in the protective scope of the present invention.

The transparent electrodes 9, 11 are arranged on the p-GaN 6 and a predetermined position 8 of the n-GaN 4, respectively, and can be made of transparent and electrically conducting indium tin oxide (ITO) or other transparent electrically conducting materials, which all fall in the protective scope of the present invention.

The p-type electrode 10 is arranged on the p-GaN 6 of the epitaxial light-emitting layer 200 or on the transparent electrode 9; and the n-type electrode 12 is provided on the n-GaN 4 or on the transparent electrode 11 that is located at a predetermined position 8 of the n-GaN 4.

In the illustrated embodiments of the present invention, the contacts 13, 14 are located on the n-type electrode 12 and the p-type electrode 10, respectively; and one of the bonding wires 15 connects the contact 13 on the n-type electrode 12 to the lead frame 1 while the other bonding wire 15 connects the contact 14 on the p-type electrode 10 to the lead frame 1. The bonding wires 15 may be made of a material selected from the group consisting of gold wires and copper wires without being limited thereto. The bonding wires 15 may also be any other electrically conducting wires, which all fall in the protective scope of the present invention.

In the third embodiment of the white light-emitting device according to the present invention as shown in FIG. 3, an adequate amount of the fluorescent powder 160 is coated on each of the epitaxial light-emitting layers 200 (i.e. the LED chips) and the transparent layer 1000 is formed over the fluorescent powder coatings 160 with only the p-type electrode 10 and the n-type electrode 12 being exposed therefrom. The exposed p-type electrode 10 and n-type electrode 12 are electrically connected via the bonding wires 15 to a base 2000 as shown in FIG. 3 or to the lead frames 1 as shown in FIGS. 1 and 2. In this manner, it is not necessary to further encapsulate the LED elements 100 with an encapsulant material. The transparent layer 1000 can be SiO₂ or Si₃N₄ without being limited thereto. It is understood all electrically insulating protective materials fall in the scope of the present invention.

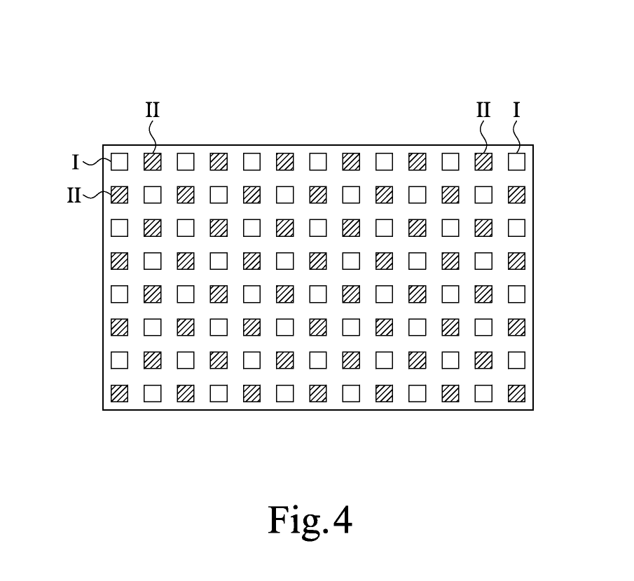

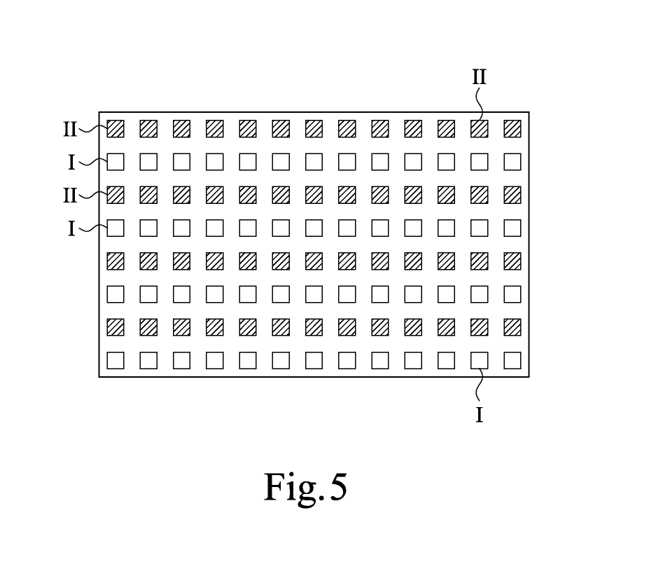

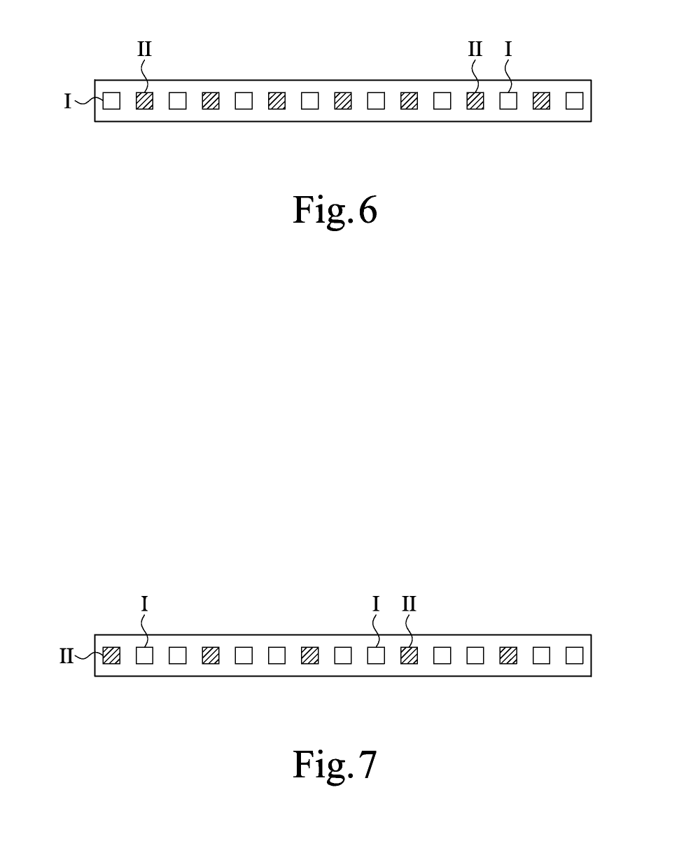

The present invention also provides a light mixing method for producing white light. Please refer to FIGS. 4, 5, 6 and 7. At least two types of the white light-emitting devices I, II of the present invention, which respectively include at least two epitaxial light-emitting layers emitting color lights with different wavelengths, can be arrayed in different manners in a module or a system, including but not limited to, being alternately arranged one by one, as shown in FIGS. 4 and 6; being alternately arranged row by row, as shown in FIG. 5; or being irregularly alternately arranged, as shown in FIG. 7. In FIG. 7, two first-type white light-emitting devices I are disposed between two second-type white light-emitting devices II.

Each type of the light-emitting device capable of producing white light according to the present invention includes at least two types of LED elements 100 and at least one encapsulant material 16. The LED elements 100 respectively includes an epitaxial light-emitting layer 200, and the epitaxial light-emitting layers 200 of the at least two LED elements 100 are of the same series of materials having different emission wavelengths. The encapsulant material 16 contains one or more types of fluorescent powder 160 that can emit excited color lights complementary to the color lights from the LED elements 100. For example, when a plurality of the first-type and second-type white light-emitting devices I, II according to the present invention are arrayed in a module or a system, at least four color lights, including for example blue light, blue-green light, green light, yellow light, orange light, red light and the like, can be emitted and mixed with one another to produce a white light with high color-rendering index and good light-mixing effect. Since all the individual white light-emitting devices I, II according to the present invention produce white light, they can be coordinately arrayed in a module or a system in different manners. In a first arraying manner as shown in FIG. 4, the first-type white light-emitting devices I and the second-type white light-emitting devices II are alternately arranged one by one. In a second arraying manner as shown in FIG. 5, the first-type white light-emitting devices I and the second-type white light-emitting devices II are alternatively arranged row by row. In a third arraying manner as shown in FIG. 6, the first-type white light-emitting devices I and the second-type white light-emitting devices II are alternately arranged one by one in one horizontal row. In a fourth arraying manner as shown in FIG. 7, the first-type white light-emitting devices I and the second-type white light-emitting devices II are irregularly alternately arranged with two first-type light-emitting devices I disposed between two second-type light-emitting devices II in one horizontal row.

Further, for the white light-emitting devices according to the present invention to produce a white light with high color-rendering index and good light mixing effect, the adequate amount of fluorescent powder 160 contained in the encapsulant material 16 is preferably any combination of yellow and red color fluorescent powder. Basically, the fluorescent powder 160 has an excitation gap smaller than the band gaps of the materials for the epitaxial light-emitting layers 200. For example, in a blue light (wavelength 460 nm) LED encapsulating structure, the epitaxial light-emitting layer 200 is AlInGaN emitting blue light and the fluorescent powder 160 is one that can be excited to emit yellow light, so that the blue light and the excited yellow light mix with each other to produce a white light. And, for an blue-green light (wavelength 495 nm) LED encapsulating structure, the epitaxial light-emitting layer 200 is AlInGaN emitting blue-green light and the fluorescent powder 160 is one that can be excited to produce red light, so that the blue-green light and the excited red light mix with each other to produce a white light. While all the above encapsulated LED light-emitting elements can emit white light, the white light emitted from the blue light LED encapsulating structure is bluish or yellowish with less red light and would therefore has somewhat higher color temperature. On the other hand, the white light emitted from the above-described blue-green light LED encapsulating structure is greenish or reddish with less blue light and would therefore has somewhat lower color temperature. Since the LED elements play a more and more important role in the backlight and illuminating device market, color saturation also becomes a more and more important factor to the LED elements. According to the present invention, by using the above-described different LED elements that all are capable of producing white light, it is able to produce blue, green, yellow and red lights, and these four color lights can mix with their respective complementary color light to produce a white light with good light mixing effect and high color-rendering index. Further, since the at least two types of LED elements in each white light-emitting device of the present invention all use the same AlInGaN series materials having very close composition, the same voltage and current can be used for control them without the need of complicated control circuits, making the white light-emitting device using same very easy to use. The white light-emitting devices for backlight or illuminating purpose are individually packaged. In the event any one of the LED elements of the white light-emitting devices is failed, the white light-emitting devices can still emit white light only with somewhat reduced overall brightness without forming other serious defects, such as changed light color (i.e. the emitted light is no longer a white light), which would otherwise occur in the prior art LED light-emitting devices. In other words, the light-emitting device capable of producing white light according to the present invention can be used over a long period of time because the overall white light illumination effect thereof is not affected by the failure of some of the LED elements thereof. With this advantage, the module and system using the white light-emitting devices of the present invention can have increased stability and service life.

Please refer to FIGS. 4 to 7. According to the light mixing method of the present invention, two types of white light-emitting devices I, II having different emission wavelengths can be used to obtain a white light through light mixing.

The first-type white light-emitting device I includes an epitaxial light-emitting layer 200 that emits a blue light having wavelength of 455 nm, and an encapsulant material 16 containing yellow fluorescent powder 160, such as YAG or Y₃A₁₅O₁₂:Ce, which can be excited to emit yellow light. The blue light and the yellow light mix with each other to produce a white light, of which the color coordinates on the chromaticity diagram developed by the International Commission on Illumination (CIE) are CIE (x)=0.304 and CIE (y)=0.335, the optical transfer ratio is 98.6%, and the color temperature is approximate 7000K. That is, the white color produced by the first-type white light-emitting device I is slightly bluish.

The second-type white LED light-emitting device II includes an epitaxial light-emitting layer 200 that emits a blue-green light having wavelength of 495 nm, and an encapsulant material 16 containing red fluorescent powder 160, such as a sulfide or an europium-doped strontium sulfide (SrS:Eu), which can be excited to emit red light. The blue-green light and the red light mix with each other to produce a white light, of which the CIE color coordinates are CIE (x)=0.403 and CIE (y)=0.391, the optical transfer ratio is 76.1%, and the color temperature is approximate 3500K. That is, the white color produced by the second-type white light-emitting device II is slightly orange-tinted. The second-type white light-emitting device II will highlight the red color of the object being illuminated. When the second-type white light-emitting device II is used with the first-type white light-emitting device I, a white light with good light mixing effect and excellent color-rendering index can be obtained to achieve the same effect as the RGB LED while solve the drawbacks thereof.

When the present invention is used in illumination and backlight applications, the above-described two types of white light-emitting devices I, II including epitaxial light-emitting layers 200 having different emission wavelengths can be used together to emit a variety of complementary color lights, and can therefore be arrayed in a module or a system to obtain increased color-rendering index and enhanced light mixing effect. The first-type and the second-type white light-emitting devices I, II can be arrayed in the module or the system in different manners. Since the epitaxial light-emitting layers 200 grown on the substrates 3 in the white light-emitting devices I, II are the same series of materials having the similar voltage property, the same control circuit can be used for them to largely reduce the complexity of the white light-emitting device of the present invention.

In FIG. 4, a plurality of the first-type white light-emitting devices I and a plurality of the second-type white light-emitting devices II are alternately arranged in the module or the system one by one. In FIG. 5, a plurality of the first-type white light-emitting devices I and a plurality of the second-type white light-emitting devices II are alternately arranged in the module or the system row by row. In FIG. 6, the first-type and the second-type white light-emitting devices I and II are alternately arranged one by one in one transverse row. However, according to the present invention, the numbers of the first-type and second-type white light-emitting devices are not necessarily in the ratio of 1:1. That is, the number of the first-type white light-emitting devices I disposed between two second-type white light-emitting devices II or the number of the second-type white light-emitting devices II disposed between two first-type white light-emitting devices I is not necessary to be one but can be adjusted according to actual need in design. For example, as can be seen in FIG. 7, a plurality of the first-type white light-emitting devices I and a plurality of the second-type white light-emitting devices II are irregularly alternately arranged in the module or the system with two first-type white light-emitting devices I being disposed between two second-type white light-emitting devices II. It is also understood, the first-type and the second-type white light-emitting devices I and II are not necessarily arrayed in the module or the system in the manners illustrated in FIGS. 4 to 7, but can be arrayed in any other suitable manners, which all fall in the protective scope of the present invention. It is also understood the numbers of the first-type white and second-type white light-emitting devices I, II are not necessarily in the ratio of 1:1 because the actual ratio of the first-type to the second-type white light-emitting devices I, II is irrelevant to the production of white light by the two types of white light-emitting devices I, II. Generally, in the visible light spectrum, there are red, orange, yellow, green, blue, indigo lights, etc. The bluish white light is a cold color light of high color temperature, and the reddish white light is a warm color light of low color temperature. Therefore, when the number of the first-type white light-emitting devices I in the module or the system is larger than that of the second-type white light-emitting devices II, the produced white light shall be a cold color light of higher color temperature. On the other hand, when the number of the second-type white light-emitting devices II in the module or the system is larger than that of the first-type white light-emitting devices I, the produced white light shall be a warm color light of lower color temperature.

With the above arrangements, at least two types of the white light-emitting devices of the present invention can be provided. The fluorescent powder 160 contained in the encapsulant material 16 for each of the white light-emitting devices absorbs the color lights emitted from the epitaxial light-emitting layers 200 grown on the substrates 3 to emit other color lights having specific wavelength ranges, and the color lights emitted from the fluorescent powder mix with the color lights emitted from the epitaxial light-emitting layers 200 to produce bluish white light to yellowish white light, or greenish white light to reddish white light.

And, in the light mixing method for producing white light according to the present invention, a first-type and a second-type white light-emitting devices I, II are provided; each of the first-type and second-type white light-emitting devices I, II includes at least two epitaxial light-emitting layers 200 grown on two substrates 3 and at least one encapsulant material 16 containing two or more types of fluorescent powder 160; the epitaxial light-emitting layers 200 for the same type of the white light-emitting devices I, II are of the same series of materials having different emission wavelengths, and the different types of fluorescent powder can be excited to emit different complementary color lights, which mix with the color lights emitted from the epitaxial light-emitting layers 200 to produce a white light; and, the two types of the white light-emitting devices I, II are arrayed in a module or a system, so that at least four different color lights, such as blue light, blue-green light, green light, yellow light, orange light and red light, are emitted and mixed to produce a white color with high color-rendering index and good light mixing effect.

With the above light mixing method, the white light-emitting devices according to the present invention for producing white light can be manufactured with simplified manufacturing process and controlled with same voltage and current to achieve the advantages of low manufacturing cost, easy to control and high good yield, making the present invention novel, improved and industrially practical for use.

The present invention has been described with some preferred embodiments thereof and it is understood that many changes and modifications in the described embodiments can be carried out without departing from the scope and the spirit of the invention that is intended to be limited only by the appended claims.

1. A light-emitting device capable of producing white light, comprising:
at least two types of light-emitting-diode (LED) elements, each of which including an epitaxial light-emitting layer, i.e. an LED chip, grown on a substrate; the epitaxial light-emitting layers for the two types of LED elements being the same series of materials to emit color lights in a region from violet to green light but having emission wavelengths different from each other by at least 30 nm; and
at least one encapsulant material for encapsulating the at least two types of LED elements and containing an adequate amount of fluorescent powder, the fluorescent powder, when being excited by the color lights emitted from the LED elements, being able to emit color lights that have specific wavelengths and are complementary to the color lights emitted from the LED elements, so that the color lights emitted from the LED elements and the excited color lights emitted from the fluorescent powder mix with one another to produce a white light.

2. The white light-emitting device as claimed in claim 1, wherein the materials of the epitaxial light-emitting layers are selected from the group consisting of AlₓGa_{y}In_{1-x-y}N and In_{z}Ga_{1-z}N, wherein 0≦x, y, z≦1.

3. The white light-emitting device as claimed in claim 1, wherein the epitaxial light-emitting layers have a structure selected from the group consisting of a single-wire vertical LED structure and a two-wire LED structure.

4. The white light-emitting device as claimed in claim 1, wherein the encapsulant material is selected from the group consisting of silicone and epoxy.

5. The white light-emitting device as claimed in claim 1, wherein each of the LED elements includes:
at least one lead frame serving as electrical connection pins;
a chip bonding glue being optionally provided on the lead frame;
the substrate being located on the chip bonding glue for formed thereon an epitaxy having a specific emission wavelength range;
two transparent electrodes being provided on the p-GaN and the n-GaN of the epitaxial light-emitting layer;
a p-type electrode being provided on the p-GaN of the epitaxial light-emitting layer or on the transparent electrode that is located on the p-GaN;
an n-type electrode being provided on the n-GaN or on the transparent electrode that is located on the n-GaN;
two contacts being provided on the p-type and the n-type electrode; and
two bonding wires for electrically connecting the contacts on the n-type and p-type electrodes to the lead frame.

6. (canceled)

7. The white light-emitting device as claimed in claim 5, wherein the chip bonding glue is selected from the group consisting of silver paste, thermally conductive and electrically insulating adhesive, metal-powder-containing adhesive, diamond-powder-containing resin, graphite-powder-containing resin, and eutectic metals.

8. A light-emitting device capable of producing white light, comprising:
at least two types of LED elements, each of which including an epitaxial light-emitting layer, i.e. an LED chip, grown on a substrate; the epitaxial light-emitting layers for the two types of LED elements being the same series of materials to emit color lights in a region from violet to green light having emission wavelengths different from each other by at least 30 nm; and
an adequate amount of fluorescent powder being coated on the epitaxial light-emitting layers; the fluorescent powder coated on the epitaxial light-emitting layers being excited by the color lights emitted from the LED elements to emit color lights having specific wavelengths and complementary to the color lights emitted from the LED elements, so that the excited color lights mix with the color lights emitted from the LED elements to produce a white light; and
a transparent layer being provided over the adequate amount of fluorescent powder coated on the epitaxial light-emitting layers.

9. The white light-emitting device as claimed in claim 8, wherein the transparent layer is formed of a material selected from the group consisting of SiO₂ and Si₃N₄.

10. The white light-emitting device as claimed in claim 8, wherein each of the LED elements has two electrodes, which are exposed from the transparent layer and are connected to a base or a lead frame of the LED element via two bonding wires.

11. The light-emitting device as claimed in claim 8, wherein the materials of the epitaxial light-emitting layers are selected from the group consisting of AlGaInN and InGaN.

12. The white light-emitting device as claimed in claim 8, wherein the epitaxial light-emitting layers have a structure selected from the group consisting of a single-wire vertical LED structure and a two-wire LED structure.

13. A light mixing method for producing white light, comprising:
providing at least two types of the white light-emitting devices as claimed in claim 1; each of the two types of the white light emitting devices including at least two types of LED elements respectively having an epitaxial light-emitting layer and at least one encapsulant material for encapsulating the LED elements; the epitaxial light-emitting layers for the LED elements being the same series of materials having different emission wavelengths; and the encapsulant material containing an adequate amount of fluorescent powder that can be excited to produce color lights complementary to color lights emitted from the LED elements; and the excited color lights and the color lights emitted from the LED elements mixing with one another to produce a white light; and
arraying a plurality of the at least two types of the white light-emitting devices in a module or a system, so that a variety of color lights is produced to mix with one another for producing a white light.

14. The light mixing method as claimed in claim 13, wherein the variety of color lights include at least four color lights selected from the group consisting of blue light, blue-green light, green light, yellow light, orange light, and red light.

15. The light mixing method as claimed in claim 13, wherein the at least two types of the white light emitting devices are arrayed in the module or the system in a manner selected from the group consisting of being alternately arranged one by one, being alternately arranged row by row, and being irregularly alternately arranged.

16. The light mixing method as claimed in claim 14, wherein the at least two types of the white light emitting devices are arrayed in the module or the system in a manner selected from the group consisting of being alternately arranged one by one, being alternately arranged row by row, and being irregularly alternately arranged.

17. A light mixing method for producing white light, comprising:
providing at least two types of the white light-emitting devices as claimed in claim 7; each of the two types of the white light emitting devices including at least two types of LED elements respectively having an epitaxial light-emitting layer and at least one encapsulant material for encapsulating the LED elements; the epitaxial light-emitting layers for the LED elements being the same series of materials having different emission wavelengths; and the encapsulant material containing an adequate amount of fluorescent powder that can be excited to produce color lights complementary to color lights emitted from the LED elements; and the excited color lights and the color lights emitted from the LED elements mixing with one another to produce a white light; and
arraying a plurality of the at least two types of the white light-emitting devices in a module or a system, so that a variety of color lights is produced to mix with one another for producing a white light.

18. The light mixing method as claimed in claim 17, wherein the variety of color lights include at least four color lights selected from the group consisting of blue light, blue-green light, green light, yellow light, orange light, and red light.

19. The light mixing method as claimed in claim 17, wherein the at least two types of the white light emitting devices are arrayed in the module or the system in a manner selected from the group consisting of being alternately arranged one by one, being alternately arranged row by row, and being irregularly alternately arranged.

20. The light mixing method as claimed in claim 18, wherein the at least two types of the white light emitting devices are arrayed in the module or the system in a manner selected from the group consisting of being alternately arranged one by one, being alternately arranged row by row, and being irregularly alternately arranged.
